(19) United States
(12) Patent Application Publication
(10) Pub. No.: US 2018/0267649 A1
(43) Pub. Date: Sep. 20, 2018

(54) ORGANIC LIGHT EMITTING TOUCH DISPLAY SCREEN

(71) Applicant: Wuhan China Sar Optoelectronics Technology Co., Lt, Wuhan, Hubei (CN)

(72) Inventor: Jian YE, Shenzhen, Guangdong (CN)

(73) Assignee: Wuhan China Star Optoelectronics Technology Co., L td., Wuhan, Hubei (CN)

(21) Appl. No.: 15/540,279

(22) PCT Filed: Mar. 29, 2017
(86) PCT No.: PCT/CN2017/078629

§ 371 Date: Jun. 28, 2017

(30) Foreign Application Priority Data
Feb. 23, 2017 (CN) 201710098524.2

(51) Int. Cl. G06F 3/046; H01L 27/32; H01L 51/52; G06F 3/041

(52) U.S. Cl. CPC G06F 3/046; H01L 27/3276; H01L 27/323; G06F 2203/04102; H01L 51/5237; G06F 3/0412; H01L 51/5281

(57) ABSTRACT

An organic light emitting touch display screen comprises an OLED display layer and a driving module. OLED display layer is layer-stacked with a cathode layer connected to the driving module. Cathode layer comprises inductive electrodes and touch control driving electrodes. In a display stage of the screen, the driving module applies display driving voltage on the cathode layer to accomplish a display function of the screen with cathode layer. In a touch stage of the screen, the driving module applies touch control voltage on said cathode layer to accomplish a touch control function of the inductive electrodes and the touch control driving electrodes. A fabricating method for an organic light emitting touch display screen is further provided.

### CROSS-REFERENCE TO RELATED APPLICATIONS

This application claims the benefit of the priority of Chinese Patent Application No. 2017100985242, entitled “Organic light emitting touch display screen”, filed on Feb. 23, 2017, disclosure of which is incorporated herein by reference.

### FIELD OF THE INVENTION

The present invention relates to a field of a touch display screen technology, and more particular to an organic light emitting touch display screen.

### BACKGROUND OF THE INVENTION

In the conventional technology, a typical approach of an Organic Light-Emitting Diode (OLED) display screen of an organic light emitting touch control screen is made by alone, and then by bonding an optical transparent adhesive on OLED, a complete touch control display screen is constituted, thereby causing an entire thickness of the touch control display screen enlarged while increase of its cost resulted from the needs of connecting the driving electrode traces and touch electrode traces to a main board since display driving electrodes and touch electrodes of the typical touch display screen obviously are located on different layers.

### SUMMARY OF THE INVENTION

The present invention provides a simplified-process organic light emitting touch display screen.

The organic light emitting touch display screen provided by the present invention, comprises an array substrate, an OLED display panel layer-stacked on said array substrate and a flexible circuit board located on a side of said array substrate, display electrode traces of said array substrate are connected to said flexible circuit board. Said OLED display panel comprises an OLED layer, and a touch electrode layer disposed in layer-stack with said OLED layer, a peripheral region of said OLED layer is deployed with via hole corresponding to touch electrode traces of said touch electrode layer, said touch electrode traces are extended through said via hole onto the same layer with the display electrode traces in said array substrate and to be connected with said flexible circuit board.

Among them, said OLED layer is covered with encapsulation layer, said via hole is located on an edge of said OLED layer and formed through said encapsulation layer.

Among them, said touch electrodes are layer-stacked above said encapsulation layer.

Among them, an insulating layer is layer-stacked above said encapsulation layer, touch electrodes of said touch electrode layer are embedded in a surface of said insulating layer that is far away from said encapsulation layer.

Among them, an insulating layer is layer-stacked above said encapsulation layer, said touch electrode layer has two layers respectively layer-stacked on a surface of said insulating layer that is far away from said encapsulation layer, and another surface of said insulating layer that is directed toward said encapsulation layer.

Among them, said flexible circuit board is disposed thereon with conductive wires corresponding to said touch electrode traces and conductive wires corresponding to the display electrode traces.

Among them, said OLED display panel is further layer-stacked thereon with a polarizer and a cover plate covering said polarizer.

Among them, said display electrode traces and said touch electrode traces are located on the same side of said array substrate.

Among them, said encapsulation layer is thin-film encapsulation.

Said organic light emitting touch display screen of the present invention integrate the OLED panel and touch control screen, and after the touch electrode traces are leaded, through the via hole disposed on the encapsulation layer, to the same layer where the display electrode traces is located, the touch electrode traces are connected to the same flexible circuit board and electrically conducted with the main board. This does not only omit a flexible circuit board but also simplifies its encapsulation process.

### BRIEF DESCRIPTION OF THE DRAWINGS

To clearly describe the structural characteristics and the beneficial effects of the present invention, the following description is detailed with accompanying figures and embodiments.

FIG. 1 depicts a cross-sectional schematic diagram of an embodiment of an organic light emitting touch display screen of the present invention;

FIG. 2 depicts a cross-sectional schematic diagram of another embodiment of an organic light emitting touch display screen of the present invention; and

FIG. 3 depicts a cross-sectional schematic diagram of another embodiment of an organic light emitting touch display screen of the present invention.

### DETAILED DESCRIPTION OF PREFERRED EMBODIMENTS

The followings will incorporate the inventive embodiments with its drawings, for more clearly and completely describing the technical solution of the inventive embodiments, wherein the drawings are regarded as just an exemplar expression, which just represents schematic diagrams but can not be realized as limited to the present invention.

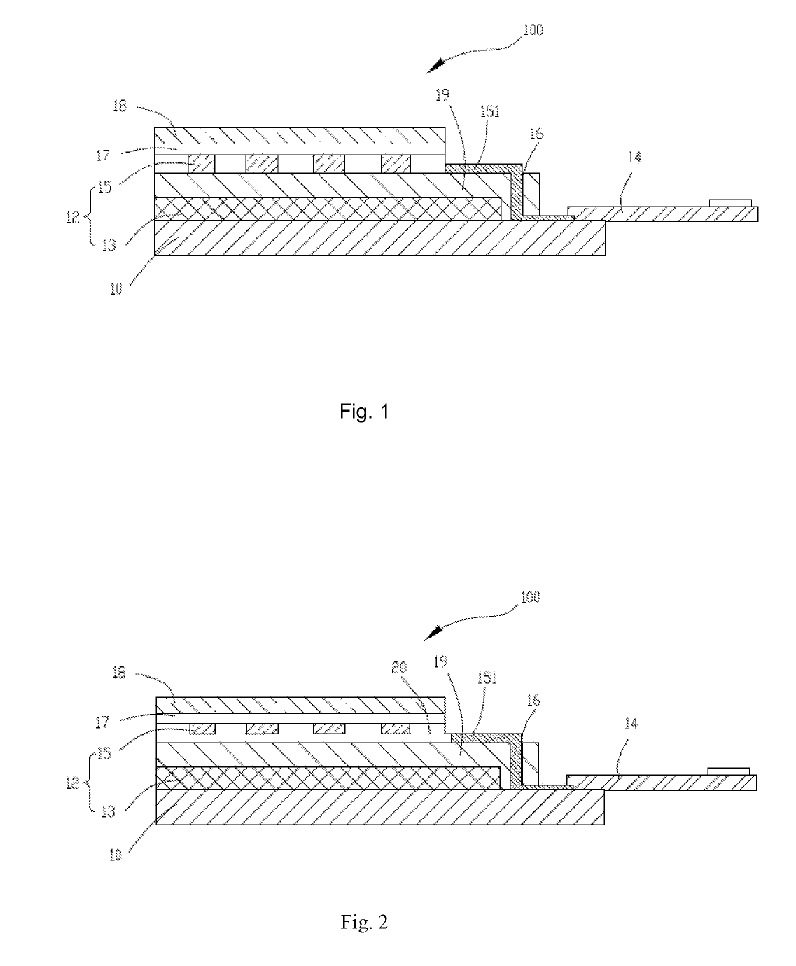

Referring to FIG. 1, the present invention provides an organic light emitting touch display screen 100, which comprises an array substrate 10, an OLED display panel 12 layer-stacked on said array substrate 10 and a flexible circuit board 14 located on a side of said array substrate 10. Display electrode traces (not shown) of said array substrate 10 are connected to said flexible circuit board 14. Said OLED display panel 12 comprises an OLED layer 13 and a touch electrode layer 15 disposed in layer-stack with said OLED layer 13. A peripheral region of said OLED layer 12 is deployed with via hole 16 corresponding to touch electrode traces 151 of said touch electrode layer 15, said touch electrode traces 151 are extended through said via hole 16 onto the same layer with the display electrode traces in said array substrate 10 and to be connected with said flexible circuit board 14.

In this embodiment, said OLED display panel 12 is further layer-stacked thereon with a polarizer 17 and a cover plate 18 covering said polarizer 17. Said polarizer 17 is bonded by optical adhesive onto said OLED display panel 12. An encapsulation layer 19 is coveringly disposed on said OLED layer 13, and said via hole 16 is located on an edge of said OLED layer 13 and formed through said encapsulation layer 19. Specifically, said encapsulation layer 19 is thin-film encapsulation which covers surface and circumferential edge of said OLED layer 13.

Said via hole 16 is numerous via holes formed through a position of an edge of said encapsulation layer 19 to the array substrate and located on a peripheral region of said OLED layer 13. Said flexible circuit board 14 is disposed thereon with conductive wires corresponding to said touch electrode traces 151, and conductive wires (not shown) corresponding to display electrode traces. The conductive wires corresponding to said touch electrode traces 151 are connected to a touch electrode control chip on said flexible circuit board 14; by the same token, the conductive wires corresponding to said display electrode traces can directly pass through flexible circuit board 14 to be connected with a main board of the organic light emitting touch display screen, and alternatively can be firstly connected to display electrode control chip on the flexible circuit board 14.

An embodiment of the organic light emitting touch display screen of the present invention is shown in FIG. 1. Said touch electrode layer 15 is stacked above said encapsulation layer 19. Said touch electrode layer 15 is formed by arranging a number of intervally-deployed touch electrodes in array, and after passing through said via hole 16 via the touch electrode traces, each row of touch electrodes are deployed on a surface of the array substrate 10 and are electrically connected by soldering method to the flexible circuit board 14 located on a side of the array substrate 10. Furthermore, said display electrode traces and said touch electrode traces 151 are located on the same side of said array substrate 10. In its fabricating process, the display electrode traces can be accomplished with a need of only one flexible circuit board 14, said touch electrode traces 151 are connected to the main board of the organic light emitting touch display screen 100, for transmitting signals to the main board. This does not only omit its process step but also saves its producing cost and reduces a volume of the organic light emitting touch display screen.

Another embodiment of the organic light emitting touch display screen of the present invention shown in FIG. 2 differs from the above-mention embodiment in that, said encapsulation layer 19 is layer-stacked thereon with an insulating layer 20, the touch electrodes of said touch electrode layer 15 are embedded in a surface of said insulating layer 20 that is far away from said encapsulation layer 19. Said touch electrode traces 151 is extended from the insulating layer 20 into said via hole 16 and onto the array substrate 10.

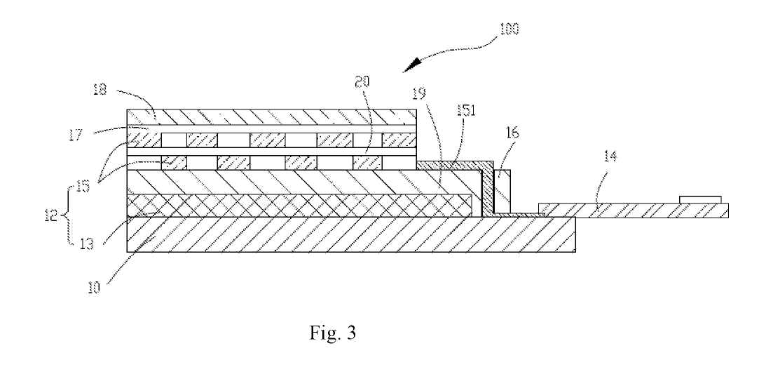

An embodiment of the organic light emitting touch display screen of the present invention is shown in FIG. 3 differs from the above-mention embodiment shown in FIG. 2 in that, said touch electrode layer 15 has two layers respectively layer-stacked on a surface of said insulating layer 20 that is far away from said encapsulation layer 19, and another surface of said insulating layer 20 that is directed toward said encapsulation layer 19. Realizably, Another approach (not shown) of this embodiment is disposing the insulating layer between a first layer as said touch electrode layer 15 and said encapsulation layer 19, and then covering the first layer by another insulating layer to form a second layer as said touch electrode layer 15.

Said organic light emitting touch display screen 100 of the present invention integrates the OLED panel with the touch control screen, disposes the touch electrodes on the OLED panel, and by the via hole disposed on the encapsulation layer, leads the touch electrode traces to the same layer where the display electrode traces are located, and to be connected to the same flexible circuit board for electrical conduction. This does not only omit a flexible circuit board but also simplifies its encapsulation process, thereby saving the producing cost of the organic light emitting touch display screen.

The aforementioned is as the preferred embodiments of the present invention, it should be to know that, to any persons who are ordinary skilled in the art, other related changes or variances not departing from principle of the present invention can be made which should be covered by the protected scope of the subject claims of the present invention.

What is claimed is:

1. An organic light emitting touch display screen, which comprises an array substrate, an OLED display panel layer-stacked on said array substrate and a flexible circuit board located on a side of said array substrate, display electrode traces of said array substrate are connected to said flexible circuit board, wherein said OLED display panel comprises an OLED layer, and a touch electrode layer disposed in layer-stack with said OLED layer, a peripheral region of said OLED layer is deployed with via hole corresponding to touch electrode traces of said touch electrode layer, said touch electrode traces are extended through said via hole onto the same layer with the display electrode traces in said array substrate and to be connected with said flexible circuit board.

2. The organic light emitting touch display screen as claimed in claim 1, wherein said OLED layer is covered with an encapsulation layer, said via hole is located on an edge of said OLED layer and formed through said encapsulation layer.

3. The organic light emitting touch display screen as claimed in claim 2, wherein said touch electrodes are layer-stacked on said encapsulation layer.

4. The organic light emitting touch display screen as claimed in claim 2, wherein an insulating layer is layer-stacked above said encapsulation layer, touch electrodes of said touch electrode layer are embedded in a surface of said insulating layer that is far away from said encapsulation layer.

5. The organic light emitting touch display screen as claimed in claim 2, wherein an insulating layer is layer-stacked above said encapsulation layer, said touch electrode layer has two layers respectively layer-stacked on a surface of said insulating layer that is far away from said encapsulation layer, and another surface of said insulating layer that is directed toward said encapsulation layer.

6. The organic light emitting touch display screen as claimed in claim 1, wherein said flexible circuit board is disposed thereon with conductive wires corresponding to said touch electrode traces and conductive wires corresponding to the display electrode traces corresponding to conductive wires.

7. The organic light emitting touch display screen as claimed in claim 1, wherein said OLED display panel is further layer-stacked thereon with a polarizer and a cover plate covering said polarizer.

8. The organic light emitting touch display screen as claimed in claim 1, wherein said display electrode traces and said touch electrode traces are located on the same side of said array substrate.

9. The organic light emitting touch display screen as claimed in claim 2, wherein said encapsulation layer is thin-film encapsulation.
